(19) United States
(12) Patent Application Publication
(10) Pub. No.: US 2019/0058306 A1
(43) Pub. Date: Feb. 21, 2019

(54) Efficient Wavelength Tunable Hybrid Laser

(71) Applicant: Futurewei Technologies, Inc., Plano, TX (US)

(72) Inventors: Yangjing Wen, Cupertino, CA (US); Yu Sheng Bai, Los Altos Hills, CA (US)

(21) Appl. No.: 16/051,165

(22) Filed: Jul. 31, 2018

Related U.S. Application Data
(60) Provisional application No. 62/547,197, filed on Aug. 18, 2017.

(51) Int. Cl. H01S 5/14; H01S 5/0687; H01S 5/10; H01S 5/062; H01S 5/06

(52) U.S. Cl. CPC H01S 5/142; H01S 5/0687; H01S 5/1092; H01S 5/343; H01S 5/1028; H01S 5/0601; H01S 5/06246

(57) ABSTRACT

A tunable hybrid laser has a gain chip and a wavelength selection chip. The wavelength selection chip includes a wavelength selective loop reflector. The wavelength selective loop reflector is configured to receive the amplified lightwave from the gain chip. The wavelength selective loop reflector includes a single optical coupler and a micro-ring resonator (MMR). The single optical coupler splits the amplified lightwave and provides portions thereof to different branches of the MRR. The MRR permits selection of a desired wavelength and reflects the portions of the amplified lightwave at the desired wavelength back to the single optical coupler, which combines the portions of the amplified lightwave at the desired wavelength to generate a reflection lightwave and a transmission lightwave. The reflection lightwave is returned to the gain chip to form the external cavity and the transmission lightwave is output from the tunable hybrid laser.

### CROSS-REFERENCE TO RELATED APPLICATIONS

This patent application claims the benefit of U.S. Provisional Patent Application No. 62/547,197, filed Aug. 18, 2017, by Yangjing Wen, et al., and titled “Efficient Wavelength Tunable Hybrid Laser,” the teaching and disclosure of which is hereby incorporated in its entirety by reference thereto.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Wavelength tunable lasers with narrow linewidth are used for coherent optical transmission networks where the lasers are used as both optical carrier and local oscillator. With the increasing of transmission capacity, higher order quadrature amplitude modulation (QAM) is being used. The higher QAM calls for narrower laser linewidth. Current external cavity lasers (ECLs) use mirrors and optics external to the gain medium to create a relatively long cavity for the laser. While exhibiting narrow laser linewidth, ECLs are bulky and are relatively costly. In addition, the tuning is relatively slow due to a mechanical tuning mechanism.

### SUMMARY

In an embodiment, the disclosure includes a tunable hybrid laser, which includes a gain chip configured to generate an amplified lightwave and a wavelength selection chip coupled to the gain chip. The wavelength selection chip includes a wavelength selective loop reflector configured to receive the amplified lightwave from the gain chip. The wavelength selective loop reflector includes a single optical coupler and at least one micro-ring resonator (MRR). The single optical coupler is configured to split the amplified lightwave and provide portions of the amplified lightwave to different branches of the at least one MRR. The at least one MRR is configured to permit selection of a desired wavelength and to reflect the portions of the amplified lightwave at the desired wavelength back to the single optical coupler. The single optical coupler is configured to combine the portions of the amplified lightwave at the desired wavelength to generate a reflection lightwave and a transmission lightwave. The reflection lightwave is returned to the gain chip to form the external cavity and the transmission lightwave is output from the tunable hybrid laser.

Optionally, in any of the preceding aspects, another implementation of the aspect provides that the gain chip comprises a semiconductor optical amplifier (SOA). Optionally, in any of the preceding aspects, another implementation of the aspect provides that a first facet of the SOA is high-reflection (HR) coated and a second facet of the SOA is anti-reflection (AR) coated. Optionally, in any of the preceding aspects, another implementation of the aspect provides that the wavelength selection chip comprises either a silicon-on-insulator (SOI) chip or a planar lightwave circuit (PLC) chip. Optionally, in any of the preceding aspects, another implementation of the aspect provides that the wavelength selection chip comprises a phase control section, the phase control section configured to pass the amplified lightwave from the gain chip to the wavelength selective loop reflector. Optionally, in any of the preceding aspects, another implementation of the aspect provides that the gain chip is butt coupled to the wavelength selection chip. Optionally, in any of the preceding aspects, another implementation of the aspect provides that the single optical coupler comprises a 2×2 optical coupler. Optionally, in any of the preceding aspects, another implementation of the aspect provides that the at least one MRR comprises two cascaded MRRs with Vernier effect. Optionally, in any of the preceding aspects, another implementation of the aspect provides a plurality of absorbers configured to absorb undesired portions of the amplified lightwave. Optionally, in any of the preceding aspects, another implementation of the aspect provides at least one monitoring photo-detector (mPD) configured to receive an undesired portion of the amplified lightwave, convert the undesired portion of the amplified lightwave to a photo-detector (PD) current, and transmit the PD current to a control circuit. Optionally, in any of the preceding aspects, another implementation of the aspect provides at least one heater operably coupled to the at least one MRR, the at least one heater configured to heat the at least one MRR based on a bias current received from the control circuit, the bias current corresponding to the PD current.

In an embodiment, the disclosure includes a tunable hybrid laser including a gain chip configured to generate an amplified lightwave and a wavelength selection chip evanescently coupled to the gain chip. The wavelength selection chip includes a phase control section and a wavelength selective loop reflector. The phase control section is configured to pass the amplified lightwave received from the gain chip to the wavelength selective loop reflector. The wavelength selective loop reflector includes a single optical coupler and at least one micro-ring resonator (MRR). The single optical coupler is configured to split the amplified lightwave and provide portions of the amplified lightwave to different branches of the at least one MRR. The at least one MRR is configured to permit selection of a desired wavelength and to reflect the portions of the amplified lightwave at the desired wavelength back to the single optical coupler. The single optical coupler is configured to combine the portions of the amplified lightwave at the desired wavelength to generate a reflection lightwave and a transmission lightwave. The reflection lightwave is returned to the gain chip via the phase control section to form the external cavity and the transmission lightwave is output from the tunable hybrid laser.

Optionally, in any of the preceding aspects, another implementation of the aspect provides that the gain chip is surface mounted on the wavelength selection chip. Optionally, in any of the preceding aspects, another implementation of the aspect provides that the gain chip comprises a semiconductor optical amplifier (SOA) and the wavelength selection chip comprises one of a silicon-on-insulator (SOI) chip and a planar lightwave circuit (PLC) chip. Optionally, in any of the preceding aspects, another implementation of the aspect provides that the single optical coupler comprises a 2×2 optical coupler and the at least one MRR comprises two cascaded MRRs with Vernier effect.

In an embodiment, the disclosure includes a method of selecting a desired wavelength in a tunable hybrid laser. The method includes amplifying a lightwave to generate an amplified wavelength with a gain chip, passing the amplified lightwave to a wavelength selective loop reflector, the wavelength selective loop reflector including a single optical coupler and at least one micro-ring resonator (MRR), splitting the amplified lightwave and providing portions of the amplified lightwave to different branches of the at least one MRR with the single optical coupler, selecting the desired wavelength of the amplified lightwave and reflecting the portions of the amplified lightwave at the desired wavelength back to the single optical coupler with the at least one MRR, combining the portions of the amplified lightwave at the desired wavelength with the single optical coupler to generate a reflection lightwave and a transmission lightwave, and returning the reflection lightwave to the gain chip via a phase control section to form the external cavity and outputting the transmission lightwave from the tunable hybrid laser.

Optionally, in any of the preceding aspects, another implementation of the aspect provides that the gain chip comprises a semiconductor optical amplifier (SOA) and a wavelength selection chip comprises one of a silicon-on-insulator (SOI) chip and a planar lightwave circuit (PLC) chip. Optionally, in any of the preceding aspects, another implementation of the aspect provides that the single optical coupler comprises a 2×2 optical coupler and the at least one MRR comprises two cascaded MRRs with Vernier effect. Optionally, in any of the preceding aspects, another implementation of the aspect provides evanescently coupling the gain chip with a wavelength selection chip containing the wavelength selective loop reflector. Optionally, in any of the preceding aspects, another implementation of the aspect provides absorbing portions of the amplified lightwave, or passing the portions of the amplified lightwave to at least one monitoring photo-detector (PD), converting the portions of the amplified lightwave to photo current, and passing the photo current to a control circuit.

For the purpose of clarity, any one of the foregoing embodiments may be combined with any one or more of the other foregoing embodiments to create a new embodiment within the scope of the present disclosure.

These and other features will be more clearly understood from the following detailed description taken in conjunction with the accompanying drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 illustrates a previously proposed wavelength tunable hybrid laser.

FIG. 2 illustrates another previously proposed external-cavity hybrid laser.

FIG. 3 illustrates an embodiment of an efficient wavelength tunable hybrid laser.

FIG. 4 illustrates an embodiment of a laser benefitting from evanescent coupling.

FIG. 5 illustrates an embodiment of a laser with an improved configuration for evanescent coupling.

FIG. 6 illustrates an embodiment of a wavelength selective loop reflector.

FIG. 7 illustrates an embodiment of a wavelength selective loop reflector.

FIG. 8 is a graph illustrating the power transfer functions of transmission and reflection of a wavelength selective loop reflector.

FIG. 9 is a schematic diagram of a network device.

FIG. 10 is an embodiment of a method of selecting a desired wavelength in a tunable hybrid laser.

### DETAILED DESCRIPTION

It should be understood at the outset that although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

Wavelength tunable lasers with narrow linewidth are crucial for coherent optical transmission networks where the lasers are used as both optical carrier and local oscillator. With the increasing of transmission capacity, higher order quadrature amplitude modulation (QAM) is being used, which requires narrower laser linewidth. Current external cavity laser (ECL) uses mirrors and optics external to the gain medium to create the laser's relatively long cavity. While exhibiting narrow laser linewidth, ECL is bulky and high cost to some extent, and the tuning is relatively slow due to a mechanical tuning mechanism.

Hybrid integration of a III-V semiconductor gain medium with silicon-on-insulator (SOI), or planar lightwave circuit (PLC) such as silicon nitride, is a promising approach to achieve small foot-print and low power consumption for tunable laser. One approach is to integrate the SOI/PLC and III-V chips based on optical coupling through butt joints. See, for example, J. L. Zhao, R. M. Oldenbeuving, J. P. Epping, M. Hoekman, R. G. Heideman, R. Dekke, Y. Fan, K.-J. Boller, R. Q. Ji, S. M. Fu, and L. Zeng, “Narrow-linewidth widely tunable hybrid external cavity laser using Si3N4/SiO2 microring resonators,” 2016 Institute of Electrical and Electronics Engineers (IEEE) 13th International Conference on Group IV Photonics (GFP), paper WC6, August 2016, and J.-H. Lee, J. Bovington, I. Shubin, Y. Luo, J. Yao, S. Lin, J. E. Cunningham, K. Raj, A. V. Krishnamoorthy, and X. Zheng, “Demonstration of 12.2% wall plug efficiency in uncooled single mode external-cavity tunable Si/III-V hybrid laser,” Opt. Exp., Vol. 23, No. 9, pp. 12079-12088, May 2015, which are each incorporated herein by reference. Once light from the III-V gain chip is coupled into SOI/PLC based waveguide, one micro-ring resonator (MRR) or multiple MRRs may be introduced to generate the feedback and form the external cavity. MRRs also function as wavelength selection and linewidth reduction.

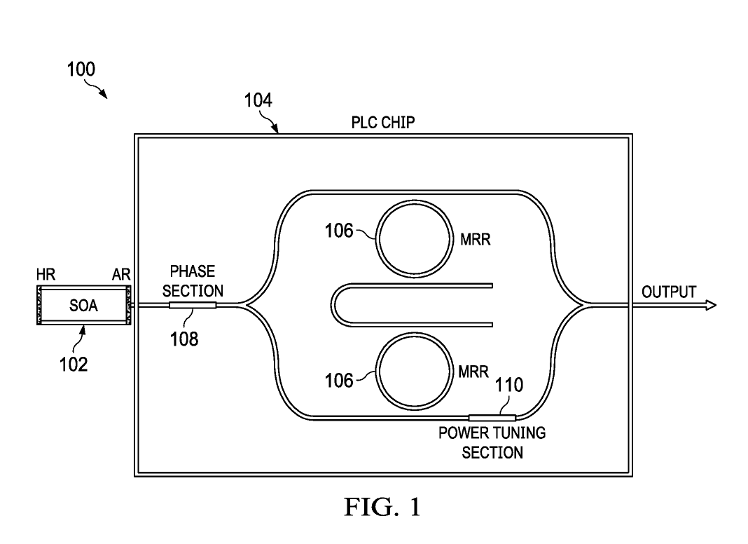

FIG. 1 illustrates a previously proposed wavelength tunable hybrid laser 100, which is based on Si3N4/SiO2 and two MRRs. The laser 100 includes an InP/InGaAsP semiconductor optical amplifier (SOA) gain chip 102 and a PLC chip 104. The PLC chip 104 includes two of the MRRs 106, a phase section 108, and a power tuning section 110. The gain chip 102 and the PLC chip 104 are butt optical coupled. The front and back facets of the gain chip 102 are high-reflection (HR) and anti-reflection (AR) coated, respectively. The MRRs 106 have slightly different radii to increase the wavelength tuning range by using the Vernier effect. The phase and power tuning sections 108, 110 are used for finely tuning the longitudinal mode and output power, respectively.

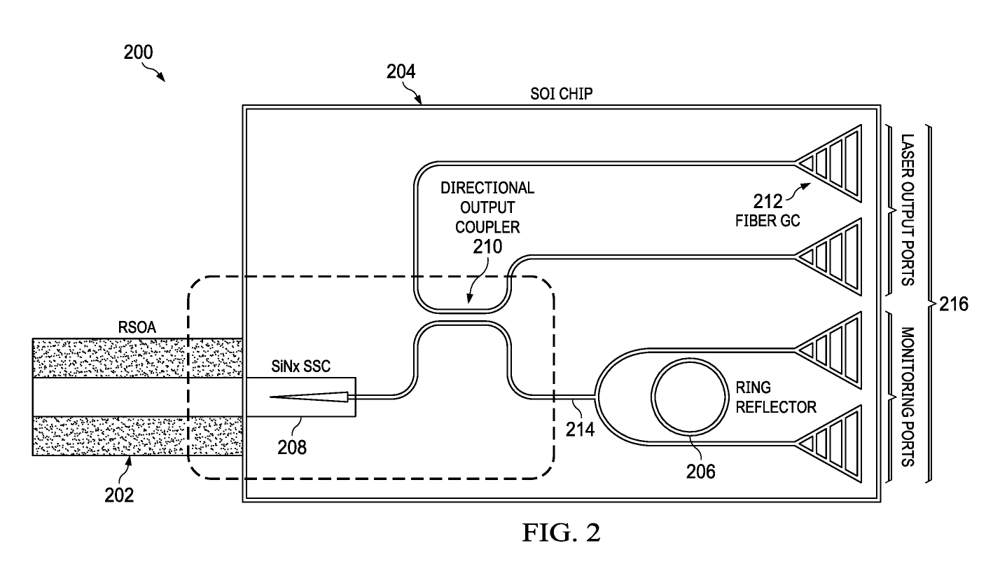

FIG. 2 illustrates another previously proposed external-cavity hybrid laser 200, which is based on a silicon photonic platform and the MRR concept. The external-cavity laser 200 is formed by butt optical coupling between an optical gain chip 202 (e.g., a reflective SOA (RSOA) or III-V chip) and a silicon on insulator (SOI) chip 204. The optical gain chip 202 provides the optical gain using, for example, InP based multiple quantum wells (MQW).

The SOI chip 204 contains a ring reflector 206, a SiNx spot size converter (SSC) 208, a directional output coupler 210, and fiber grating couplers (GCs) 212. Wavelength selectivity and tunability are provided by a micro-ring filter in SOI chip 204. The ring reflector 206 is a loop type micro-ring reflector composed of a Y-junction 214 and a ring 206, which provide a broad free spectral range (FSR) that enables wavelength-selective feedback. All output ports 216 are connected to their respective fiber GCs 212 to provide multiple laser outputs.

For the scheme shown in FIG. 1, the pass/reflection ratios of the two add-drop MRRs 106 are relatively difficult to control, and an additional power tuning section is required to generate a single output. For the scheme shown in FIG. 2, the additional directional optical coupler 210 between the loop type reflector 206 and the gain chip 202 induces higher round trip loss due to the double pass of light in the optical coupler 210. The additional directional optical coupler 210 also induces excess insertion loss, with the wasted optical power going to the output ports 216 labeled monitoring ports.

Disclosed herein is an efficient wavelength tunable hybrid laser. In an embodiment, the laser includes a gain chip, a phase control section, and a 2×2 optical coupler based loop type wavelength selective reflector. In an embodiment, the laser includes a 2×2 optical coupler and two cascaded micro-ring resonators (MRRs) with Vernier effect. In an embodiment, the laser includes a 2×2 optical coupler and a single MRR. The reflected light from the loop reflector returns back to the gain chip to self-seed the laser and facilitate single mode operation. The transmitted light from the loop reflector forms the output of the wavelength tunable hybrid laser. The laser of the present disclosure has a simpler and more efficient configuration relative to conventional lasers. The configuration reduces the round trip loss in the external cavity for a given output power, allows the output power to be easily controlled, and eliminates the need for a power tuning section.

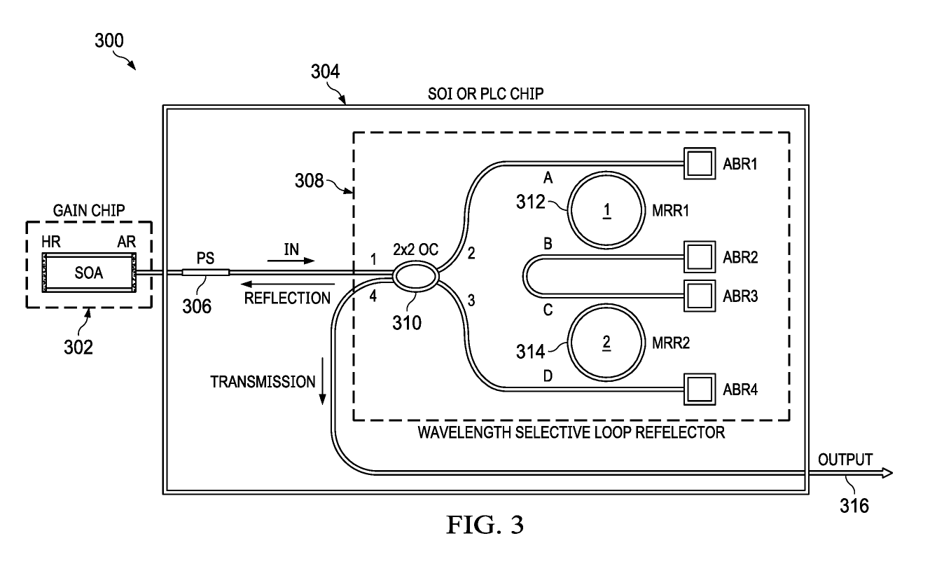

FIG. 3 illustrates an embodiment of an efficient wavelength tunable hybrid laser 300. The laser 300 comprises a gain chip 302 and a SOI or PLC chip 304 (SOI/PLC chip), which are butt optical coupled. In an embodiment, the gain chip 302 is a III-V semiconductor-based material like InP, which provides gain for lasing. In an embodiment, the gain chip 302 is a semiconductor optical amplifier (SOA) with one facet high-reflection (HR) coated and the other facet anti-reflection (AR) coated.

The SOI/PLC chip 304 includes a phase control section (PS) 306 and a wavelength selective loop reflector 308. The phase control section 306 is configured to receive output light from the gain chip 302. The phase control section 306 is also configured to reflect light (a.k.a., feedback light) from the wavelength selective loop reflector 308. The phase control section 306 operates to adjust the phase of the feedback light to finely tune the longitudinal mode of the laser 300. In an embodiment, the phase control section 306 is optional.

In an embodiment, the wavelength selective loop reflector 308 is based on a single optical coupler 310 (e.g., a 2×2 optical coupler) and a pair of cascaded MRRs 312, 314, which are labeled MRR1 and MRR2 for ease of reference. As shown in FIG. 3, the optical coupler 310 includes two input ports, which are labeled 1 and 4, and two output ports, which are labeled 2 and 3.

In an embodiment, MRR1 312 is formed by waveguides A and B and a micro-ring labeled 1, while MRR2 314 is formed by waveguides C and D and a micro-ring labeled 2. The MRRs 312, 314 may be referred to as add-drop MRRs. As shown, waveguides B and C are coupled together.

In an embodiment, waveguide A is coupled to an absorber, labeled ABR1, waveguide B is coupled to an absorber, labeled ABR2, waveguide C is coupled to an absorber, labeled ABR3, and waveguide D is coupled to an absorber, labeled ABR4. The absorbers ABR1, ABR2, ABR3, and ABR4 are configured to dissipate unwanted reflected light.

In an embodiment, the MRRs 312, 314 are configured to provide the Vernier effect. In such cases, the MRRs 312, 314 have slightly different free spectral ranges (FSRs) in order to increase the wavelength tuning range by using the Vernier effect.

After being launched into the SOI/PLC chip 304, the light output from the gain chip 302 is sent into the phase control section 306. The light is then input into the loop type wavelength selective reflector 308 (as depicted by the arrow and the word “In” in FIG. 3). The light launched into the loop type wavelength selective reflector 308 is sent to the optical coupler 310 via port 1, where the light is separated into two parts. One part of the light is output through port 2, transmits in clockwise direction, and is then sent to waveguide A. The other part is output through port 3, transmits in counter clockwise direction, and is then sent to waveguide D.

In the clockwise direction, the light into waveguide A is added to MRR1 312, dropped to waveguide B, and then sent to waveguide C. A portion of the light, which may be referred to as the MRR pass portion, is sent to absorber ABR1. The light into waveguide C is added to MRR2 314, dropped to waveguide D, and returned to the optical coupler 310 via port 3. The MRR pass portion of the light is sent to absorber ABR3.

Meanwhile, in the counter clockwise direction, the light into waveguide D is added to MRR2 314, dropped to waveguide C, and then sent to waveguide B. The MRR pass portion of the light is sent to absorber ABR4. The light into waveguide B is added to MRR1 312, dropped to waveguide A, and returned to the optical coupler 310 via port 2. The MRR pass portion of the light is sent to absorber ABR2. It should be noted that there can be different ways to dissipate the unwanted reflections other than using absorbers ABR1-ABR4. For example, the waveguides A-D can be extended to the edge of the SOI/PLC chip 304, which is itself AR coated or angled. Other options are discussed below in context.

The two returned lights received by the optical coupler 310 at port 3 and port 2 are combined to generate two outputs, namely a reflection light (as depicted by the arrow and the word “Reflection” in FIG. 3) and a transmission light (as depicted by the arrow and the word “Transmission” in FIG. 3). The reflection light is sent back toward the gain chip 302 via port 1 of the optical coupler 310. The reflection light (a.k.a., reflected light or feedback light) is adjusted by the phase control section 306 to finely tune the longitudinal mode of the laser 300. In addition, the reflection light is sent back to the gain chip 302 via the phase control section 306 to form the external cavity, self-seed the gain chip 302 (e.g., the laser diode), and facilitate single mode operation. The transmission light is transmitted from port 4 of the optical coupler 310. As shown in FIG. 3, the transmitted light becomes the output 316 of the wavelength tunable hybrid laser 300.

By using the single optical coupler 310, certain advantages and benefits are realized. For example, use of the light within the laser 300 is improved relative to a conventional laser. That is, the light is not unduly wasted. In addition, the power tuning section (as shown in FIG. 1) is not needed, and the output power is less sensitive to fabrication tolerance. Also, the laser 300 in FIG. 3 is able to make full use of the optical power compared to, for example, the laser 200 in FIG. 2.

As previously noted, the laser 300 uses butt optical coupling to integrate the gain chip 302 with the SOI/PLC chip 304. In practice, the coupling process requires precise alignment (e.g., vertical, horizontal, and angular alignment) due to the small size of the laser beam. If not performed properly, butt joint coupling may suffer from undesired reflection at the coupling facet. To avoid such difficulties, evanescent coupling is utilized in an embodiment.

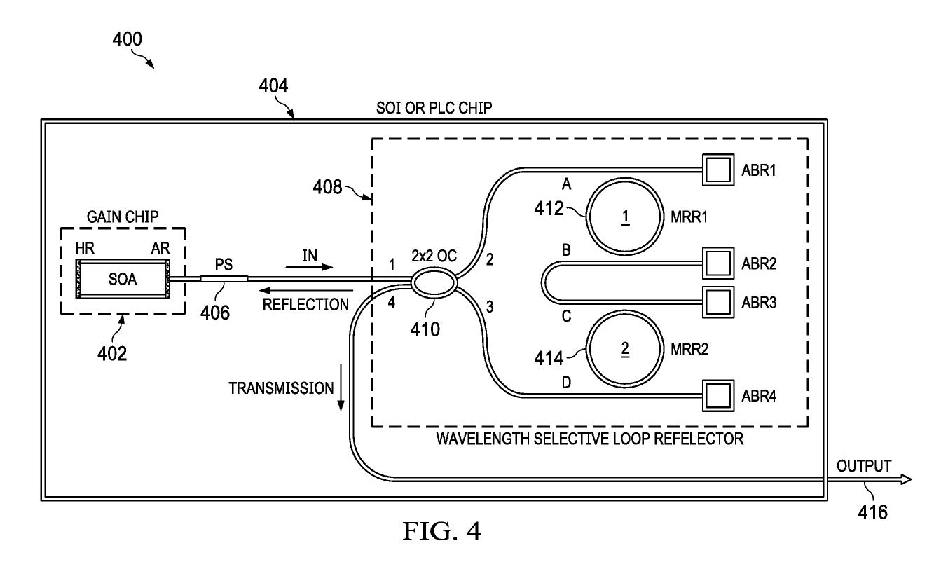

FIG. 4 illustrates an embodiment of a laser 400 benefitting from evanescent coupling. As shown, the laser 400 includes a gain chip 402 and an SOI/PLC chip 404. The laser 400, gain chip 402, and SOI/PLC chip 404 of FIG. 4 may be similar to the laser 300, gain chip 302, and SOI/PLC chip 304 of FIG. 3. As such, the laser 400 also includes a phase control section 406 and a wavelength selective loop reflector 408 that contains an optical coupler 410 and MRRs 412, 414. The laser 400 is also configured to generate an output 416.

However, in contrast to the laser 300 of FIG. 3, the gain chip 402 and the SOI/PLC chip 404 are evanescently coupled instead of being optically butt coupled. In an embodiment, the gain chip 402 is surface mounted onto the SOI/PLC chip 404 to effectuate the coupling. In an embodiment, the gain chip 402 is flip-chip mounted onto the SOI/PLC chip 404 to effectuate the coupling.

As shown in FIG. 4, a III-V semiconductor gain chip 402 (a.k.a., high-index III-V laser waveguide) is evanescently coupled to the SOI/PLC chip 404 (e.g., low-index SOI/PLC waveguide) via direct contact where transverse-transfer occurs between the laser active area and SOI/PLC waveguide. If the coupling is not done properly, a large index contrast between the low-index SOI/PLC waveguide and high-index III-V laser waveguide makes the evanescent coupling problematic due to modal mismatch.

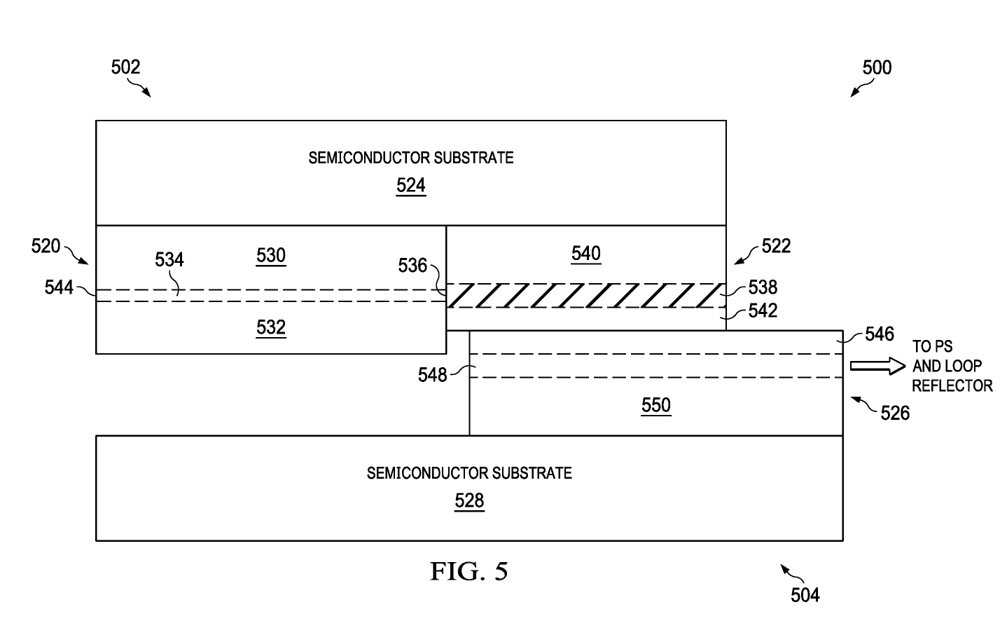

FIG. 5 illustrates an embodiment of a laser 500 with an improved configuration for evanescent coupling. In practical applications, the laser 500 may include an alignment/support structure, which is not shown in FIG. 5. However, an alignment/support structure is found in, for example, H. A. Blauvlet, D. W. Vernooy, J. S. Paslaski, C. I. Grosjean, H. Lee, F. G. Monzon, and K. H. Nguyen, “Etched-facet semiconductor optical component with integrated end-coupled wave-guide and methods of fabrication and use thereof,” U.S. Pat. No. 7,599,585, which is incorporated herein by reference.

The laser 500 may be similar to the laser 300, 400 of FIGS. 3-4. For example, the laser 500 includes a gain chip 502 and a SOI/PLC chip 504. In an embodiment, the gain chip 502 comprises a planar laser waveguide 520 end-coupled to a PLC waveguide 522, both on a semiconductor substrate 524. In an embodiment, the SOI/PLC chip 504 comprises an SOI/PLC waveguide 526 on a semiconductor substrate 528 (e.g., a silicon (Si) substrate, etc.). The SOI/PLC chip 504 includes or is connected to other components like a phase control section and a wavelength selective loop reflector (not shown). The gain chip 502 is coupled to the SOI/PLC chip 504 via evanescent coupling between the end-coupled PLC waveguide 522 and SOI/PLC waveguide 526.

In an embodiment, the planar laser waveguide 520 (or SOA) comprises upper and lower laser confinement layers 530 and 532, respectively, surrounding active laser layer 534. In an embodiment, the active laser layer 534 comprises a III-V semiconductor multiple-quantum well. The laser confinement layers 530/532 are able to provide both optical confinement of gain chip optical modes as well as charge carrier confinement for localizing optical gain within the planar laser waveguide 520.

After spatially selective material processing to form planar laser waveguide 520 with end-face 536, and application of any optical coating(s) on the end-face 536 (if needed), the end-coupled SOI/PLC waveguide 526 (a.k.a., integrated planar optical waveguide) may be formed using a silicon nitride core 538 and silica-based upper and lower cladding layers 540/542. The thickness of lower waveguide cladding layer 542 is chosen so as to substantially align the silicon nitride core 538 with the active laser layer 534. The vertical and lateral dimensions of core 538 near the proximal end of the end-coupled PLC waveguide 522 are chosen to achieve the required degree of spatial mode matching.

The planar laser waveguide 520 may include at its other end an end-face 544, which may be high-reflection coated. Prior to fabrication of the PLC waveguide 522, the end-face 536 of the planar laser waveguide 520 may be anti-reflection coated. The end-face 536, the end-face 544, and the planar laser waveguide 520 collectively form a laser resonator structure. The light generated from planar laser waveguide 520 is first end-coupled into the PLC waveguide 522, which is then evanescent-coupled (also referred to as side-coupling, transverse-transfer, or directional coupling) to the SOI/PLC waveguide 526. In an embodiment, the SOI/PLC waveguide 526 comprises an upper cladding layer 546, a core layer 548, and lower cladding layer 550, which are coupled to other components like the phase control section and the wavelength selective loop reflector as described herein.

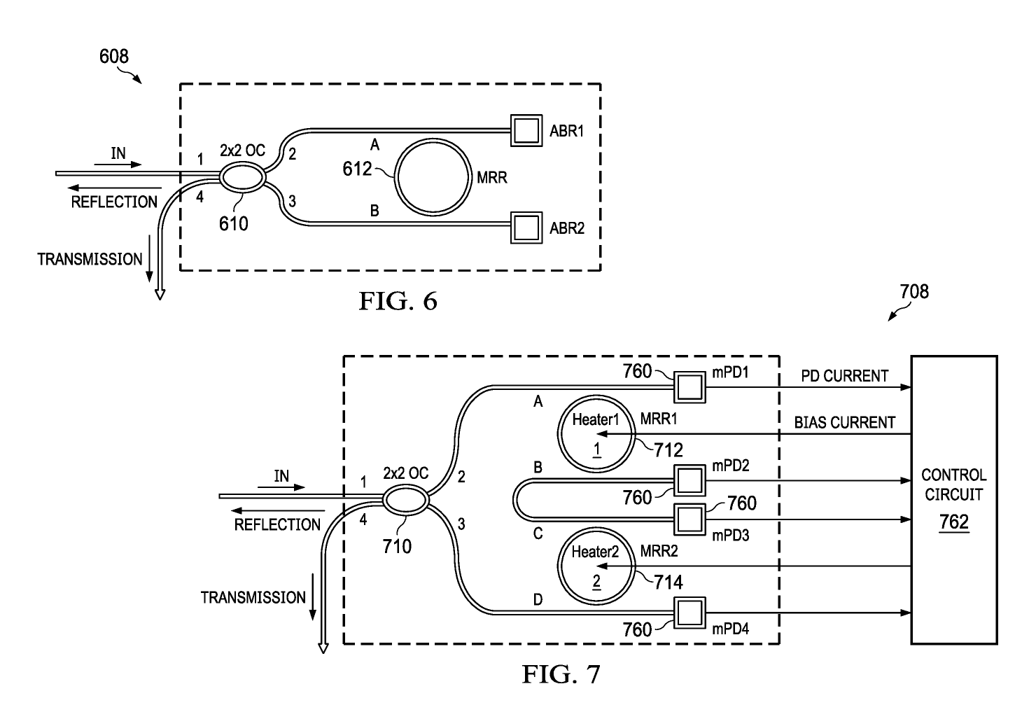

FIG. 6 illustrates an embodiment of a wavelength selective loop reflector 608. The wavelength selective loop reflector 608 may be utilized within a laser such as the efficient wavelength tunable hybrid lasers 300, 400. Unlike the wavelength selective loop reflectors 308, 408 in FIGS. 3-4, the wavelength selective loop reflector 608 employs a single optical coupler 610 and a single MRR 612. In an embodiment, the single optical coupler 610 is a 2×2 optical coupler. As such, the light launched into the wavelength selective loop reflector 608 (represented by the arrow and the text “In”) is first sent to the optical coupler 610 via port 1 and is separated into two parts. One part of the light is output through port 2, transmits in clockwise direction, and is then sent to waveguide A. The other part is output through port 3, transmits in a counter clockwise direction, and is then sent to waveguide B.

In clockwise direction, the light into waveguide A is added to the MRR 612, dropped to waveguide B, and returned to the optical coupler 610 via port 3. A portion of the light, which may be referred to as the MRR pass portion, is sent to absorber ABR1. Meanwhile, in the counter clockwise direction, the light is first added to MRR 612 from waveguide B, dropped to waveguide A, and returned to the optical coupler 610 via port 2. The MRR pass portion of the light is sent to absorber ABR2.

The two returned lights received by the optical coupler 610 at port 3 and port 2 are combined to generate two outputs, namely a reflection light (as depicted by the arrow and the word “Reflection” in FIG. 6) and a transmission light (as depicted by the arrow and the word “Transmission” in FIG. 6). The reflection light is sent back to a gain chip (not shown) via the phase control section to form the external cavity, self-seed to the internal cavity light, and facilitate single mode operation. The transmission light becomes the output of the wavelength tunable hybrid laser.

For the wavelength selective loop reflector 608 (a.k.a., single MRR based loop reflector), the FSR of the MRR 612 is relatively large, such as tens of nanometers and larger than the gain bandwidth of the gain chip (SOA). Therefore, only one wavelength can oscillate and a single mode operation can be achieved.

The absorbers ABR1-ABR4 in FIGS. 3-4 and the absorbers ABR1-ABR2 in FIG. 6 are introduced to absorb unwanted reflected light (a.k.a., the MRR pass portion light) so that no undesired reflection is returned back to the gain chip 302, 402. The absorber may be in a variety of forms, including but not limited to, an optical attenuator, a monitoring photo-detector (mPD), or an mPD together with an optical attenuator. When the mPD and the optical attenuator are used together, the optical attenuator is placed between the MRR and the mPD. The output of each mPD may be used to, for example, control a heater attached to its MRR to tune the resonance wavelength.

FIG. 7 illustrates an embodiment of wavelength selective loop reflector 708. The wavelength selective loop reflector 708 is similar to the wavelength selective loop reflector 308, 408, and 608 of FIGS. 3-4 and 6. For example, the wavelength selective loop reflector 708 includes a single optical coupler 710 (e.g., a 2×2 optical coupler) and a pair of cascaded MRRs 712, 714, which are labeled MRR1 and MRR2 for ease of reference. The optical coupler 710 includes two input ports, which are labeled 1 and 4, and two output ports, which are labeled 2 and 3. MRR1 712 is formed by waveguides A and B and a micro-ring labeled 1, while MRR2 714 is formed by waveguides C and D and a micro-ring labeled 2. The waveguides B and C are coupled together.

The wavelength selective loop reflector 708 also uses mPDs 760 as the absorbers, which are labeled mPD1, mPD2, mPD3, and mPD4. The MRR pass portion light from each MRR 712, 714 is sent to its corresponding mPD 760 to convert the light into a PD current, which is then sent to the feedback control circuit 762. The PD current from mPD1 and mPD2 is fed into the control circuit 762 to generate a first control bias current. The first control bias current is sent to a heater, labeled Heater 1, attached to MRR1 712 to tune its resonance wavelength. Similarly, the PD current from mPD3 and mPD4 is fed into the control circuit 762 to generate a second control bias current. The second control bias current is sent to a heater, labeled Heater 2, attached to MRR2 714 to tune its resonance wavelength.

The single optical coupler 310, 410, 610, 710 in FIGS. 3-4 and 6-7 can be a directional coupler or a multi-mode interference (MMI) coupler. In the implementation, a proper power cross-coupling ratio is selected to optimize the laser performance. If the power cross-coupling ratio of the coupler is defined as K, the power reflection transfer function R can be expressed as:

R=4K(1−K)H₁(f)H₂(f) (1)

And the power transmission transfer function T can be expressed as:

T=(1−2K)²H₁(f)H₂(f), (2)

where H₁ and H₂ are the power transfer function of the drop port for MRR1 and MRR2, respectively. For the case of a single MRR, H₂ is not included in equations (1) and (2).

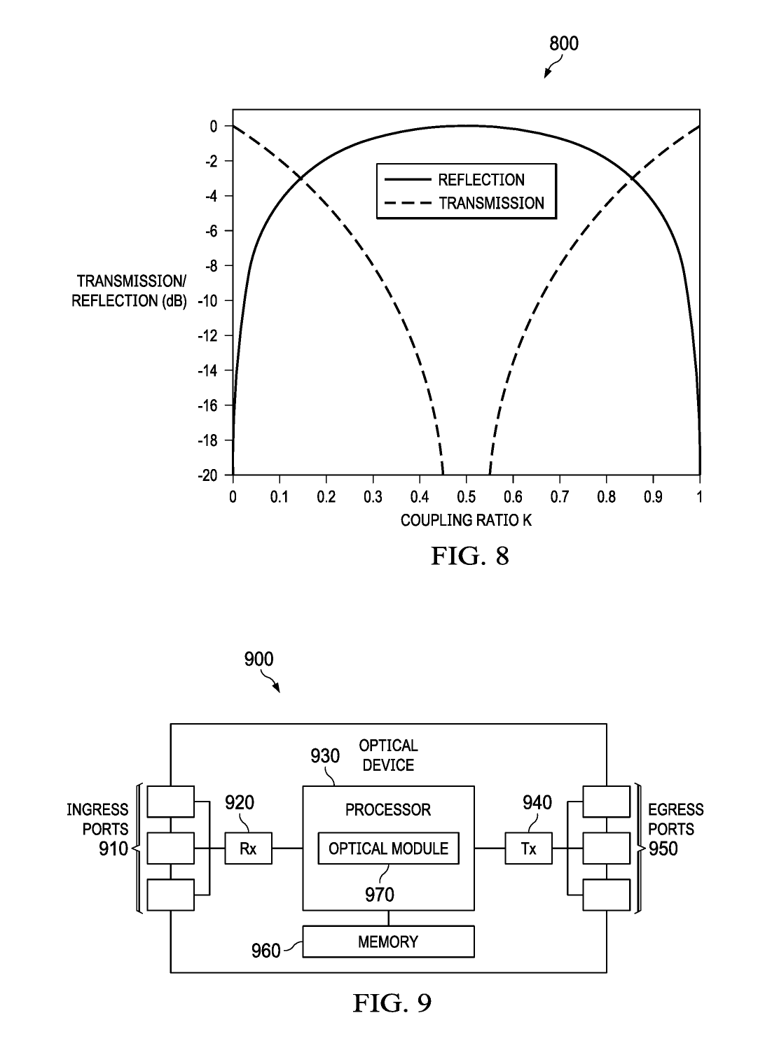

FIG. 8 is a graph 800 illustrating the power transfer functions of transmission and reflection of a wavelength selective loop reflector (a.k.a., a loop type reflector), ignoring the insertion loss of the MRRs. As shown, the graph 800 depicts the coupling ratio K on the x-axis and the transmission/reflection, which is measured in decibels (dB), on the y-axis.

The graph 800 illustrates that transmission and reflection are complementary to each other. When the coupling ratio K has a value of 0.5 (e.g., 50%), there is full reflection and no transmission. When K has a value of 1 (e.g., 100%), there is full transmission and no reflection. When K is around 0.146 (e.g., 14.6%) or around 0.854 (e.g., 85.4%), there is equal transmission and reflection, which adds in about a 3 dB round trip external cavity loss.

FIG. 9 is a schematic diagram of an optical device 900 according to an embodiment of the disclosure. The optical device 900 is suitable for implementing the disclosed embodiments as described herein. The optical device 900 comprises ingress ports 910 and receiver units (Rx) 920 for receiving data; a processor, logic unit, or central processing unit (CPU) 930 to process the data; transmitter units (Tx) 940 and egress ports 950 for transmitting the data; and a memory 960 for storing the data. The optical device 900 may also comprise optical-to-electrical (OE) components and electrical-to-optical (EO) components coupled to the ingress ports 910, the receiver units 920, the transmitter units 940, and the egress ports 950 for egress or ingress of optical or electrical signals.

The processor 930 is implemented by hardware and software. The processor 930 may be implemented as one or more CPU chips, cores (e.g., as a multi-core processor), field-programmable gate arrays (FPGAs), application specific integrated circuits (ASICs), and digital signal processors (DSPs). The processor 930 is in communication with the ingress ports 910, receiver units 920, transmitter units 940, egress ports 950, and memory 960. The processor 930 comprises an optical module 970. The optical module 970 implements the disclosed embodiments described above. For instance, the optical module 970 implements one or more various optical operations. The inclusion of the optical module 970 therefore provides a substantial improvement to the functionality of the optical device 900 and effects a transformation of the optical device 900 to a different state. Alternatively, the optical module 970 is implemented as instructions stored in the memory 960 and executed by the processor 930.

The memory 960 comprises one or more disks, tape drives, and solid-state drives and may be used as an over-flow data storage device, to store programs when such programs are selected for execution, and to store instructions and data that are read during program execution. The memory 960 may be volatile and/or non-volatile and may be read-only memory (ROM), random access memory (RAM), ternary content-addressable memory (TCAM), and/or static random-access memory (SRAM).

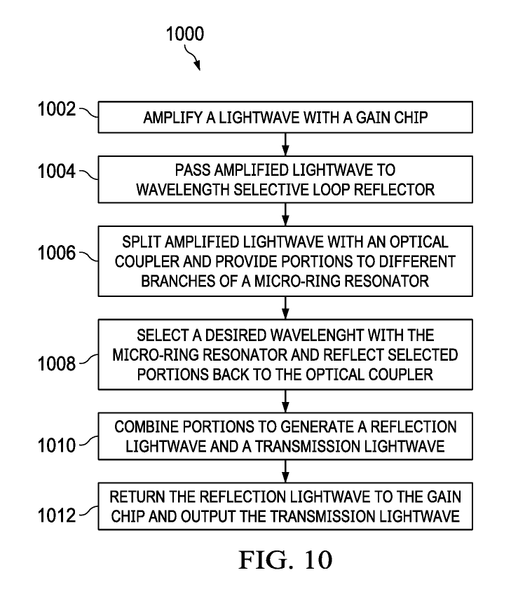

FIG. 10 is a method 1000 of selecting a desired wavelength. The method may be implemented by the hybrid laser 300, 400 of FIGS. 3-4 or the optical device 900 of FIG. 9 as disclosed herein. In block 1002, a lightwave is amplified to generate an amplified wavelength with a gain chip. In block 1004, the amplified lightwave is passed to a wavelength selective loop reflector. In an embodiment, the wavelength selective loop reflector includes a single optical coupler and at least one MRR. In block 1006, the amplified lightwave is split with the single optical coupler and portions of the amplified lightwave are provided to different branches of the at least one MRR.

In block 1008, the desired wavelength of the amplified lightwave is selected with the at least one MRR and the portions of the amplified lightwave at the desired wavelength are reflected back to the single optical coupler. In block 1010, the portions of the amplified lightwave at the desired wavelength are combined with the single optical coupler to generate a reflection lightwave and a transmission lightwave. In block 1012, the reflection lightwave is returned to the gain chip to form the external cavity and the transmission lightwave is output from the tunable hybrid laser. In an embodiment, the reflection lightwave is returned to the gain chip via the phase section.

In an embodiment, the disclosure includes a tunable hybrid laser means, which includes gain means configured to generate an amplified lightwave and wavelength selection means coupled to the gain means. The wavelength selection means includes a wavelength selective loop reflector means configured to receive the amplified lightwave from the gain means. The wavelength selective loop reflector means includes a single optical coupler means and at least one micro-ring resonator (MRR) means. The single optical coupler means is configured to split the amplified lightwave and provide portions of the amplified lightwave to different branches of the at least one MRR means. The at least one MRR means is configured to permit selection of a desired wavelength and to reflect the portions of the amplified lightwave at the desired wavelength back to the single optical coupler means. The single optical coupler means is configured to combine the portions of the amplified lightwave at the desired wavelength to generate a reflection lightwave and a transmission lightwave. The reflection lightwave is returned to the gain means to form the external cavity and the transmission lightwave is output from the tunable hybrid laser means.

In an embodiment, the disclosure includes a tunable hybrid laser means including a gain means configured to generate an amplified lightwave and a wavelength selection means evanescently coupled to the gain means. The wavelength selection means includes a phase control means and a wavelength selective loop reflector means. The phase control means is configured to pass the amplified lightwave received from the gain means to the wavelength selective loop reflector means. The wavelength selective loop reflector means includes a single optical coupler means and at least one micro-ring resonator (MRR) means. The single optical coupler means is configured to split the amplified lightwave and provide portions of the amplified lightwave to different branches of the at least one MRR means. The at least one MRR means is configured to permit selection of a desired wavelength and to reflect the portions of the amplified lightwave at the desired wavelength back to the single optical coupler means. The single optical coupler means is configured to combine the portions of the amplified lightwave at the desired wavelength to generate a reflection lightwave and a transmission lightwave. The reflection lightwave is returned to the gain means via the phase control means to form the external cavity and the transmission lightwave is output from the tunable hybrid laser means.

In an embodiment, the disclosure includes a method of selecting a desired wavelength in a tunable hybrid laser means. The method includes amplifying a lightwave to generate an amplified wavelength with a gain means, passing the amplified lightwave to a wavelength selective loop reflector means, the wavelength selective loop reflector means including a single optical coupler means and at least one micro-ring resonator (MRR) means, splitting the amplified lightwave and providing portions of the amplified lightwave to different branches of the at least one MRR means with the single optical coupler means, selecting the desired wavelength of the amplified lightwave and reflecting the portions of the amplified lightwave at the desired wavelength back to the single optical coupler with the at least one MRR means, combining the portions of the amplified lightwave at the desired wavelength with the single optical coupler means to generate a reflection lightwave and a transmission lightwave, and returning the reflection lightwave to the gain means via a phase control means to form the external cavity and outputting the transmission lightwave from the tunable hybrid laser means.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A tunable hybrid laser, comprising:
a gain chip configured to generate an amplified lightwave;
a wavelength selection chip coupled to the gain chip, the wavelength selection chip comprising a wavelength selective loop reflector configured to receive the amplified lightwave from the gain chip, the wavelength selective loop reflector including a single optical coupler and at least one micro-ring resonator (MRR), the single optical coupler configured to split the amplified lightwave and provide portions of the amplified lightwave to different branches of the at least one MRR, the at least one MRR configured to permit selection of a desired wavelength and to reflect the portions of the amplified lightwave at the desired wavelength back to the single optical coupler, the single optical coupler configured to combine the portions of the amplified lightwave at the desired wavelength to generate a reflection lightwave and a transmission lightwave, the reflection lightwave returned to the gain chip to form the external cavity and the transmission lightwave output from the tunable hybrid laser.

2. The tunable hybrid laser of claim 1, wherein the gain chip comprises a semiconductor optical amplifier (SOA).

3. The tunable hybrid laser of claim 2, wherein a first facet of the SOA is high-reflection (HR) coated and a second facet of the SOA is anti-reflection (AR) coated.

4. The tunable hybrid laser of claim 1, wherein the wavelength selection chip comprises either a silicon-on-insulator (SOI) chip or a planar lightwave circuit (PLC) chip.

5. The tunable hybrid laser of claim 1, wherein the wavelength selection chip comprises a phase control section, the phase control section configured to pass the amplified lightwave from the gain chip to the wavelength selective loop reflector.

6. The tunable hybrid laser of claim 1, wherein the gain chip is butt coupled to the wavelength selection chip.

7. The tunable hybrid laser of claim 1, wherein the single optical coupler comprises a 2×2 optical coupler.

8. The tunable hybrid laser of claim 1, wherein the at least one MRR comprises two cascaded MRRs with Vernier effect.

9. The tunable hybrid laser of claim 1, further comprising a plurality of absorbers configured to absorb undesired portions of the amplified lightwave.

10. The tunable hybrid laser of claim 1, further comprising at least one monitoring photo-detector (mPD) configured to receive an undesired portion of the amplified lightwave, convert the undesired portion of the amplified lightwave to a photo-detector (PD) current, and transmit the PD current to a control circuit.

11. The tunable hybrid laser of claim 10, further comprising at least one heater operably coupled to the at least one MRR, the at least one heater configured to heat the at least one MRR based on a bias current received from the control circuit, the bias current corresponding to the PD current.

12. A tunable hybrid laser, comprising:
a gain chip configured to generate an amplified lightwave; and
a wavelength selection chip evanescently coupled to the gain chip, the wavelength selection chip comprising a phase control section and a wavelength selective loop reflector, the phase control section configured to pass the amplified lightwave received from the gain chip to the wavelength selective loop reflector, the wavelength selective loop reflector including a single optical coupler and at least one micro-ring resonator (MRR), the single optical coupler configured to split the amplified lightwave and provide portions of the amplified lightwave to different branches of the at least one MRR, the at least one MRR configured to permit selection of a desired wavelength and to reflect the portions of the amplified lightwave at the desired wavelength back to the single optical coupler, the single optical coupler configured to combine the portions of the amplified lightwave at the desired wavelength to generate a reflection lightwave and a transmission lightwave, the reflection lightwave returned to the gain chip via the phase control section to form the external cavity and the transmission lightwave output from the tunable hybrid laser.

13. The tunable hybrid laser of claim 12, wherein the gain chip is surface mounted on the wavelength selection chip.

14. The tunable hybrid laser of claim 12, wherein the gain chip comprises a semiconductor optical amplifier (SOA) and the wavelength selection chip comprises one of a silicon-on-insulator (SOI) chip and a planar lightwave circuit (PLC) chip.

15. The tunable hybrid laser of claim 12, wherein the single optical coupler comprises a 2×2 optical coupler and the at least one MRR comprises two cascaded MRRs with Vernier effect.

16. A method of selecting a desired wavelength in a tunable hybrid laser, comprising:
amplifying a lightwave to generate an amplified wavelength with a gain chip;
passing the amplified lightwave to a wavelength selective loop reflector, the wavelength selective loop reflector including a single optical coupler and at least one micro-ring resonator (MRR);
splitting the amplified lightwave and providing portions of the amplified lightwave to different branches of the at least one MRR with the single optical coupler;
selecting the desired wavelength of the amplified lightwave and reflecting the portions of the amplified lightwave at the desired wavelength back to the single optical coupler with the at least one MRR;
combining the portions of the amplified lightwave at the desired wavelength with the single optical coupler to generate a reflection lightwave and a transmission lightwave; and
returning the reflection lightwave to the gain chip via a phase control section to form the external cavity and outputting the transmission lightwave from the tunable hybrid laser.

17. The method of claim 16, wherein the gain chip comprises a semiconductor optical amplifier (SOA) and a wavelength selection chip comprises one of a silicon-on-insulator (SOI) chip and a planar lightwave circuit (PLC) chip.

18. The method of claim 16, wherein the single optical coupler comprises a 2×2 optical coupler and the at least one MRR comprises two cascaded MRRs with Vernier effect.

19. The method of claim 16, further comprising evanescently coupling the gain chip with a wavelength selection chip containing the wavelength selective loop reflector.

20. The method of claim 16, further comprising absorbing portions of the amplified lightwave, or passing the portions of the amplified lightwave to at least one monitoring photo-detector (PD), converting the portions of the amplified lightwave to photo current, and passing the photo current to a control circuit.
